(19) United States
(12) Patent Application Publication
(10) Pub. No.: US 2012/0062219 A1
(43) Pub. Date: Mar. 15, 2012

(54) SENSOR DEVICE FOR MAGNETIC PARTICLES WITH A HIGH DYNAMIC RANGE

(75) Inventor: Cristian B. Craus, Helmond (NL)

(73) Assignee: KONINKLIJKE PHILIPS ELECTRONICS N.V., EINDHOVEN (NL)

(21) Appl. No.: 13/321,186

(22) PCT Filed: May 12, 2010
(86) PCT No.: PCT/IB10/52106

§ 371 Date: Nov. 18, 2011

(30) Foreign Application Priority Data
May 19, 2009 (EP) 09160645.9

(51) Int. Cl. G01R 33/12

(52) U.S. Cl. 324/228

(57) ABSTRACT

The invention relates to a method and a sensor device (100) for the detection of magnetic particles (M) in a sample. The magnetic particles (M) can bind to binding sites (Z) at a binding surface (12), where they can be detected by a detection unit (13, 14). A controller (15) is provided for controlling magnetic attraction (B) of the magnetic particles (M) towards the binding surface (12) in dependence on the detection signal (S) of the detection unit (14) in such a way that rotational relaxation conditions for the magnetic particles (M) are changed. In particular, this change can be controlled to maximize the binding of magnetic particles (M) to the binding surface (12) within a given measurement time. The change can for example be achieved by repeatedly switching the magnetic attraction off for prolonged periods, giving the magnetic particles (M) better chances to orient properly with respect to the binding surface (12).

The invention relates to a method and a sensor device for the detection of magnetic particles in a sample, wherein said particles can specifically bind to binding sites at a binding surface. Moreover, it relates to the use of such a device.

In the U.S. Pat. No. 6,991,938, an assay is described for the quantitative determination of a component that binds to a solid body. A detection signal is continuously monitored and used to infer the amount of the component in a sample. A challenge for this and similar methods is that in practice they have to cope with a large dynamic range of the unknown concentration, said range typically covering at least three decades.

Based on this background, it was an object of the present invention to provide means that allow an accurate detection of target particles in a sample over a wide dynamic range of concentrations.

This object is achieved by a sensor device according to claim 1, a method according to claim 2, and a use according to claim 14. Preferred embodiments are disclosed in the dependent claims.

According to its first aspect, the invention relates to a sensor device for the detection of magnetic particles in a sample. In this context, the term “magnetic particle” shall comprise particles that are permanently magnetic as well as magnetizable particles, particularly micro-particles or nano-particles. The sample will typically be a fluid, for example a body fluid like blood or saliva. The sensor device comprises the following components:

a) A “sample chamber” that comprises a surface (called “binding surface” in the following) with binding sites at which the magnetic particles can bind. The binding sites may for example be antibodies that can specifically bind to antigens attached to the magnetic particles. In general, there will typically be a covalent binding between the binding sites and the magnetic particles.

The sample chamber is typically an empty cavity or a cavity filled with some substance like a gel that may absorb a sample substance; it may be an open cavity, a closed cavity, or a cavity connected to other cavities by fluid connection channels.

b) A “magnetic field generator” for attracting magnetic particles to the binding surface. The magnetic field generator may for example be realized by a permanent magnet or an electromagnet that generates a magnetic field with a nonzero gradient in the sample chamber such that magnetic particles are magnetized and pulled into the direction of the gradient.

c) A “detection unit” for providing a detection signal that is related to the amount of magnetic particles bound to the binding surface.

d) A controller for controlling the magnetic attraction in dependence on the aforementioned detection signal such that rotational relaxation conditions for the magnetic particles are changed according to a predetermined criterion. The controller will typically be realized by dedicated electronic hardware and/or digital data processing hardware, and it will usually control the magnetic field generator to affect the magnetic attraction.

Moreover, the term “rotational relaxation” refers to the rotation of magnetic particles that, starting from some initial orientation, takes place due to thermal movement (“Brownian motion”). If magnetic attraction is strong, there will be hardly any rotational relaxation because the magnetic particles are forced by the magnetic field to keep the prevailing orientation. If the magnetic field is however weak or even zero, the magnetic particles become free to rotate under the influence of their thermal energy.

The invention further relates to a corresponding method for the detection of magnetic particles in a sample, said method comprising the following steps (which will typically be executed in parallel):

a) Magnetically attracting magnetic particles to a binding surface where they can bind to binding sites.

b) Detecting with a detection unit magnetic particles that are bound to the binding surface.

c) Controlling the magnetic attraction of step a) in dependence on the detection results of step b) to purposefully change rotational relaxation conditions for the magnetic particles.

The method comprises in general form the steps that can be executed with a sensor device of the kind described above. Reference is therefore made to the above description for more information on the details of this method.

The sensor device and the method allow a fast detection of magnetic particles in a sample due to the possibility that these particles can be magnetically attracted to a binding surface where they are sensed. Besides this, the sensor device and the method take influence on the rotational relaxation of the magnetic particles. This step is motivated by the insight that the binding kinetics can thus be positively affected. In particular, rotational relaxation may deliberately be used to increase the chances of binding by allowing the magnetic particles to assume a proper orientation with respect to the binding surface. The sensor device and the method thus provide a new operational parameter that can be controlled to improve the outcome of a detection, for example with respect to accuracy and/or dynamic range.

In the following, preferred embodiments of the invention will be described that relate to both the sensor device and the method described above.

In many practical applications, the magnetic particles will only be used as an indicator or label for some target particles one is actually interested in, e.g. for biological substances like biomolecules, complexes, cell fractions or cells. The magnetic particles may for example be used in a competition assay in which they compete with target particles of the sample for the binding sites at the binding surface; the amount of bound magnetic particles will then be inversely related to the unknown concentration of target particles. According to a preferred embodiment of the invention, the magnetic particles are able to bind at least one target particle. To this end, the magnetic particles may for instance carry one or more antibodies which are specific for said target particles. Thus target particles can be labeled with magnetic particles, and the detected amount of magnetic particles is an indicator for the (unknown) amount of target particles in the sample.

In a further development of the aforementioned approach, the design of magnetic particles and binding sites is such that only magnetic particles with at least one bound target particle can bind to the binding surface. This is for example the case if target particles are a necessary connector between a binding site on the binding surface and a magnetic particle. In this embodiment, the amount of magnetic particles that are bound to the binding surface is immediately related to the amount of target particles in the sample.

The detection signals or results that are provided by the detection unit and that indicate the amount of magnetic particles bound to the binding surface are used by the controller to adapt the magnetic attraction in some predetermined way. Preferably, the detection signals or results of the detection unit are additionally monitored and evaluated by an evaluation unit with respect to the concentration of target particles in the sample which interact with the magnetic particles. An important example of an interaction between target particles and magnetic particles is given in the aforementioned embodiment, in which the magnetic particles can bind at least one target particle. As already mentioned, it is usually the concentration of target particles one is actually interested in. The evaluation unit helps to provide this desired information based on a monitoring of detection signals, i.e. based on the kinetics of binding at the binding surface.

The affectation of the rotational relaxation of the magnetic particles can be exploited to improve a measurement with respect to a variety of different objectives from which a user may select. In a particularly important example, magnetic attraction is controlled (and rotational relaxation conditions are changed) such that the binding of magnetic particles to the binding surface is maximized within a given measurement time. In this way the accuracy of the measurement can be increased while still complying with constraints imposed by an application, for example the limited time available for a measurement in a roadside drug test.

Another particular approach comprises to control magnetic attraction such that better conditions for rotational relaxation are provided in case the actual detection signals indicate a low binding rate of magnetic particles to the binding surface. To explain this approach, the above example may be considered in which magnetic particles can only bind to the binding surface via target particles: (a) At very low concentrations of target particles, a low binding rate of magnetic particles to the binding surface will be caused by a (too) small amount of magnetic particles with bound target particles near the binding surface; better conditions for rotational relaxation will in this case also improve the conditions for translational relaxation, i.e. for diffusion, which helps to exchange free magnetic particles near the binding surface with magnetic particles that carry a target particle. (b) At somewhat higher concentrations of target particles, there may be enough magnetic particles with bound target particles near the binding surface; however, they may not have a proper orientation for a binding to occur. Better conditions for rotational relaxation will in this case allow the magnetic particles to assume a broader range of different orientations, thus increasing their chances to reach the binding surface with a proper orientation for a binding.

The control of magnetic attraction is preferably done based on stored calibration data. The comparison of actual detection signals with such stored calibration data will then allow the controller to decide if there is a necessity to change magnetic attraction. In the aforementioned example, such a change would for example be initiated if the detection signals resemble calibration data that correspond to a low binding rate.

In general, the magnetic attraction that is exerted on magnetic particles to pull them to the binding surface may follow any temporal course or pattern that achieves a desired purpose. In a preferred embodiment, the magnetic attraction oscillates with a controlled frequency (typically ranging between 1 Hz and 100 Hz).

The aforementioned oscillations of the magnetic attraction may for example have a sinusoidal course. In a preferred embodiment, the magnetic attraction is repeatedly switched between just two values, i.e. a “high” and a “low” magnitude, with a controlled duty cycle. Most preferably, the low magnitude corresponds to zero magnetic attraction (magnetic field generator switched off). As usual, the term “duty cycle” shall denote the ratio between the time magnetic attraction is “high” and the duration of one period (i.e. the total time of one “high” and “low” cycle). As rotational relaxation of magnetic particles will be inversely related to the magnitude of magnetic attraction, conditions for rotational relaxation can readily be controlled via the duty cycle.

According to a particularly preferred control scheme, which may optionally be realized in combination with the aforementioned one, the magnetic attraction is switched off for periods of controlled duration. Typically, these periods will range between 1 ms and 1000 ms, most preferably between 10 ms and 100 ms. As rotational relaxation can substantially only occur when magnetic attraction is switched off, controlling the duration of these periods provides a direct measure to influence the conditions of rotational relaxation.

The measurements of the detection unit will usually sense all magnetic particles that are close to the binding surface, whether bound or not. To restrict the detection to the actually bound magnetic particles, it is therefore preferred that unbound magnetic particles are removed from the binding surface prior to a detection step. Such a removal may for example be achieved by completely exchanging the adjacent fluid. More preferably, a “magnetic washing” may be applied during which magnetic particles are magnetically repelled from the binding surface (or, equivalently, attracted to a distant point above the binding surface) with a force that does not disrupt existing bindings.

The detection unit preferably comprises an optical, magnetic, mechanical, acoustic, thermal and/or electrical sensor element. A magnetic sensor element may particularly comprise a coil, Hall sensor, planar Hall sensor, flux gate sensor, SQUID (Superconducting Quantum Interference Device), magnetic resonance sensor, magneto-restrictive sensor, or magneto-resistive sensor of the kind described in the WO 2005/010543 A1 or WO 2005/010542 A2, especially a GMR (Giant Magneto Resistance), a TMR (Tunnel Magneto Resistance), or an AMR (Anisotropic Magneto Resistance). An optical sensor element may particularly be adapted to detect variations in an output light beam that arise from a frustrated total internal reflection due to magnetic particles at a sensing surface. Other optical, mechanical, acoustic, and thermal sensor concepts are described in the WO 93/22678, which is incorporated into the present text by reference.

The invention further relates to the use of the device described above for molecular diagnostics, biological sample analysis, chemical sample analysis, food analysis, and/or forensic analysis. Molecular diagnostics may for example be accomplished with the help of magnetic beads or fluorescent particles that are directly or indirectly attached to target molecules.

These and other aspects of the invention will be apparent from and elucidated with reference to the embodiment(s) described hereinafter. These embodiments will be described by way of example with the help of the accompanying drawings in which:

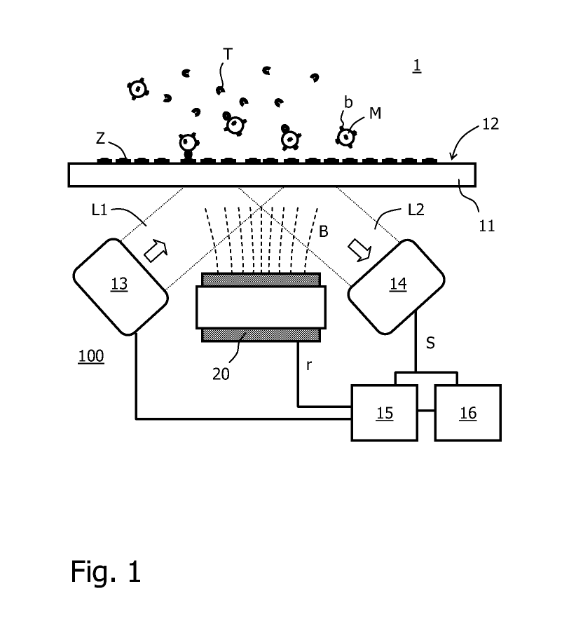

FIG. 1 schematically illustrates a sensor device according to the present invention;

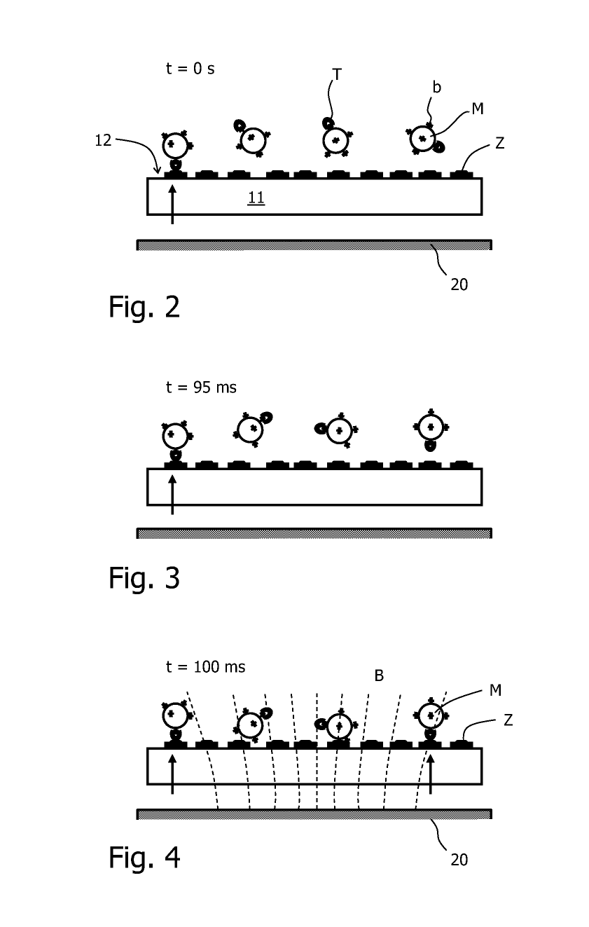

FIGS. 2-4 illustrate conditions at the binding surface before and while magnetic attraction is switched on;

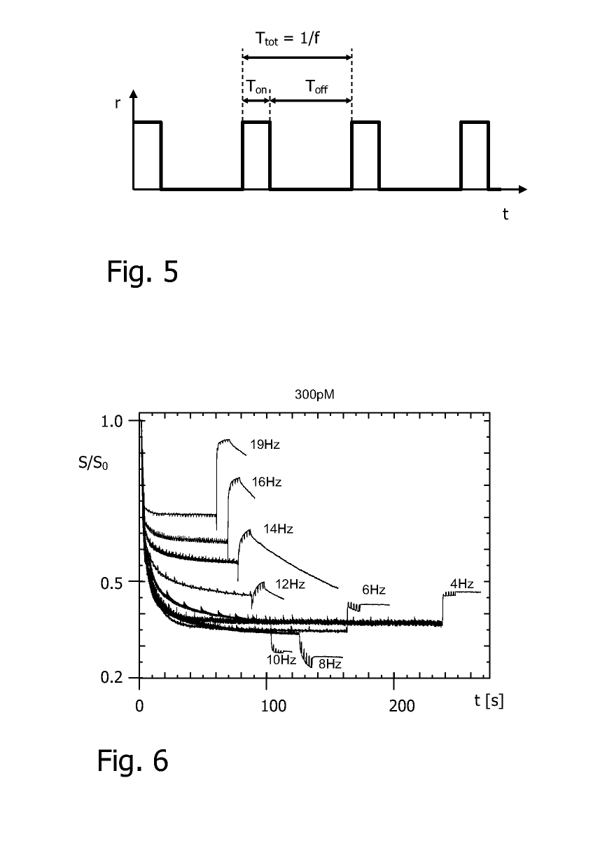

FIG. 5 shows the switching pattern of the magnetic attraction;

FIG. 6 illustrates measured detection signals for a given concentration of target particles and different frequencies of magnetic attraction;

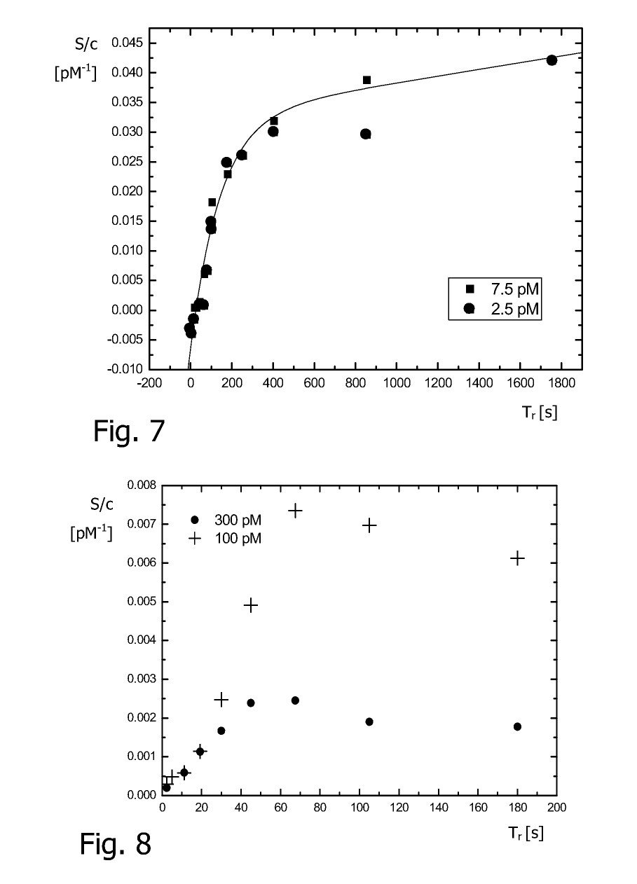

FIGS. 7 and 8 illustrate measured detection signals, normalized with the corresponding concentration of target particles, for different total relaxation times.

Like reference numbers in the Figures refer to identical or similar components.

The development of instrumentation for providing rapid diagnostics at the point of care (POC) and in emergency conditions is an important topic in the field of molecular diagnostics (MD). The principal requirements for a MD platform are the speed of diagnose, sufficient sensitivity, and ease to use. In addition to this, disposables with micro-fluidic channels are preferred to increase flexibility of the platform towards a large number of manufacturers.

For many applications, the chosen diagnosis method is based on performing immunoassays. Here, possible detection methods comprise inter alia frustrated total internal reflection (FTIR) using magnetic labels and confocal fluoroscopy using molecular fluorescent labels. Although both methods are sensitive enough in detecting very small variations of the labels, one has to ensure the stability of all physical aspects that can influence the intrinsic biochemical properties of the assay component. By using superparamagnetic beads one has the possibility to influence directly the kinetics of the assays such that the detection procedure can be performed within a limited amount of time. For cardiac Troponin assays, this period is for example less than 5 minutes starting from the moment when the sample is introduced into the cartridge.

Furthermore, the dynamic range of the system must cover at least three decades for many immunoassays. This is difficult to satisfy based on protocols developed especially for high sensitivity. Possible solutions to this problem are related either to an end point detection (EPD) or to a continuous signal monitoring (CSM). Usually in EPD the assay is performed in a number of steps where the assay is interrupted and the signal is assumed to be given predominantly by the labels with analyte molecules. In CSM assays, kinetic measurements are performed. In other words, standard samples are used in order to calibrate the assay both with respect to time and analyte concentration, the estimation of the detected analyte concentration of an unknown sample being made by comparing the measurement data with the calibration curves.

In view of the above background, an alternative approach is proposed here which extends the dynamic range of a MD platform and is not based on magnetic washing procedures. In addition also a way of maximizing the accuracy of the platform is offered. The basic idea of this approach is to use rotational relaxation phenomena of the magnetic particles (beads). These phenomena are taking place in periods when no magnetic field gradient present. During this time and depending on the bead radius, a reorientation process will take place such that a magnetic bead will have a changed orientation with respect to the surface capture antibodies. The binding to the surface will take place in a subsequent step when the magnetic field gradient is switched on again. In this last step, the bonding will take place during the time when the field gradient is activated.

FIG. 1 schematically shows a sensor device 100 that realizes the above general principles. Though the following description refers to a particular setup (using frustrated total internal reflection as measurement principle), it is not limited to such an approach and can favorably be used in many different applications and setups.

The sensor device 100 comprises a carrier 11 that may for example be made from glass or transparent plastic like polystyrene. The carrier 11 is located next to a sample chamber 1 in which a sample fluid with target components T to be detected (e.g. drugs, antibodies, DNA, etc.) can be provided. The sample further comprises magnetic particles, for example superparamagnetic beads M, wherein each of these particles comprises (via e.g. a coating with antibodies) at least one binding site b for the aforementioned target components T. During an incubation time at the beginning of an assay, magnetic particles M and target particles T will therefore bind to a degree that depends on their concentrations.

The interface between the carrier 11 and the sample chamber 1 is formed by a surface called “binding surface” 12. This binding surface 12 is coated with binding sites Z, e.g. antibodies, which can specifically bind to target particles T that are bound to magnetic particles M. In the Figure, such a binding is shown for one magnetic particle.

The sensor device 100 further comprises a light source 13 that generates an input light beam L1 which is transmitted into the carrier 11. As light source 13, e.g. a commercial CD (λ=780 nm), DVD (λ=658 nm), or BD (λ=405 nm) laser-diode can be used. A collimator lens may be used to make the input light beam L1 parallel, and a pinhole of e.g. 0.5 mm may be used to reduce the beam diameter. The input light beam L1 arrives at the binding surface 12 at an angle larger than the critical angle of total internal reflection (TIR) and is therefore totally internally reflected in an “output light beam” L2. The output light beam L2 leaves the carrier 11 and is detected by a light detector 14. The light detector 14 determines the amount of light of the output light beam L2 (e.g. expressed by the light intensity of this light beam in the whole spectrum or a certain part of the spectrum). The measured detection signals S are monitored and evaluated by an evaluation unit 16 that is coupled to the detector 14.

The described sensor device uses the principle of frustrated total internal reflection (FTIR). This principle is based on the fact that an evanescent wave penetrates (exponentially dropping in intensity) into the sample 1 when the incident light beam L1 is totally internally reflected. If this evanescent wave then interacts with another medium like the bound magnetic particles M, part of the input light will be coupled into the sample fluid (this is called “frustrated total internal reflection”), and the reflected intensity will be reduced (while the reflected intensity will be 100% for a clean interface and no interaction). Depending on the amount of disturbance, i.e. the amount of magnetic particles on or very near (within about 200 nm) to the TIR surface 12 (not in the rest of the sample chamber 1), the reflected intensity will drop accordingly. This intensity drop is a direct measure for the amount of bound magnetic particles M, and therefore for the concentration of target particles T in the sample.

The sensor device 100 further comprises a magnetic field generator 20, for example an electromagnet with a coil and a core, for controllably generating a magnetic field B at the binding surface 12 and in the adjacent space of the sample chamber 1. With the help of this magnetic field, the magnetic particles 1 can be manipulated, i.e. be magnetized and particularly be moved (if magnetic fields with gradients are used). Thus it is for example possible to attract magnetic particles 1 to the binding surface 12 in order to accelerate their binding to said surface, or to wash unbound target particles away from the binding surface before a (final) measurement.

The magnetic field generator 20 is connected to a controller 15 which receives the detection signals S from the light detector 14. Based on this information, the controller 15 can control the magnet 20 in such a way that rotational relaxation conditions of the magnetic particles M are affected in a desired way.

This is illustrated in more detail in FIGS. 2 to 4. The Figures show magnetic particles M with one bound target particle T each in front of the binding surface 12 at three consecutive time points. FIG. 2 shows the situation at the time t=0 s. One magnetic particle is already bound to a binding site Z at the binding surface 12 (cf. arrow), and the magnet 20 is switched off. If the residual magnetic particles would at this point in time be magnetically attracted to the binding surface 12, none of them would have a proper orientation of its bound target particle that would allow a binding.

FIG. 3 shows the situation at t=95 ms. As there is no magnetic attraction yet, the magnetic particles M were free to rotate according to their thermal energy.

In FIG. 4, the situation is shown at t=100 ms. The magnet 20 has been switched on and generates a magnetic field B with a gradient that attracts the magnetic particles to the binding surface 12. Due to the intermediate rotation, the rightmost magnetic particle M is now properly oriented, i.e. with its target particle directed to the binding surface 12. Hence, this magnetic particle can attach to a binding site Z (cf. second arrow).

Quantitative analysis shows that the damping time of translational and angular velocities for diffusion of spherical particles are comparable and have a ratio of 3/10. Correction factors can be introduced depending on the volume fraction of the particles, hydrodynamic and potential interactions. As an example, a magnetic bead M having a radius of 250 nm may be considered that is dispensed in water. In the infinite dilution approximation, the relaxation time τᵣ of such a bead is

$${τ}_{r} = \frac{8 π η {r}^{3}}{{k}_{B} T} = 100 ms ,$$

whereas the distance I covered due to translational diffusion is only

$$l = \sqrt{\frac{2 {k}_{B} Tt}{3 {π}^{2} η r}} = 100 nm .$$

This is important especially at small concentrations of the target particles when the amount of beads without any captured target particles becomes significant. As a consequence the beads which are in the proximity of the surface need to be exchanged with new beads.

The second important region of target particle concentration is where no volume mixing is required over the duration of an experiment. In that case, provided that the bead-target particle incubation is under control, the amount of beads with captured target particles situated in the proximity of the binding surface is proportional to the concentration of target particles in the sample volume.

To illustrate the effect of the rotational relaxation time, measurements were performed at various concentrations of target particles (here: target molecules), wherein only the total time available for relaxation, i.e. the total time during which the magnetic attraction was zero, was varied while all other parameters were maintained constant. In other words, for attraction of the magnetic beads towards the binding sites Z actuation schemes were used in which the magnetic attraction was repeatedly switched on and off for the same number (900) of actuation cycles and with the same duration of the “on” periods (50 ms). However, the duration of the “off” periods (i.e. the duty cycle)—and hence the switching frequency f—was modified. The attraction due to an electromagnet placed below the printed spot was also the same in all experiments. At the end of each 900 attraction cycles, another electromagnet placed on the opposite side of the sample chamber (microchannel) was used to remove all unbound and nonspecifically bound beads from the binding surface. It should be noted that the target particles and the beads were mixed and kept together the same amount of time before starting each actuation procedure.

FIG. 5 illustrates the described switching pattern for the control command r that is issued from the controller 15 to the magnet 20, wherein a value of “1” means that the magnet is switched “on” and a value of “0” that it is “off”. Each period or cycle has a total length Tₜₒₜ which is the inverse of the switching frequency f (the value that occurs in FIG. 6) and which is composed of the duration Tₒₙ the magnet is “on” and the duration T_{off} it is “off”. The duty cycle of activation would then be defined as the ratio Tₒₙ/Tₜₒₜ.

FIG. 6 shows the measurement results for one concentration of the target particles (300 pM) and for different switching frequencies f ranging from 4 Hz to 19 Hz. The vertical axis shows the detection signal in relative units, while the horizontal axis represents time t. As the number and duration of the “on” periods is the same for all curves, the duration of the “off” periods (and thus the time available for rotational relaxation) increases with decreasing frequency.

It can be seen that the endpoint-signal measured at the end of each entire actuation procedure is decreasing with the total time that is available for rotational relaxation.

FIGS. 7 and 8 show graphs representing the (endpoint-) signal normalized to the target particle (here: TroponinI) concentration c versus the total time available for relaxation, Tᵣ, measured as described above. FIG. 7 refers to low concentrations of target particles where the maximum number of target particles per bead is less than one at the end of the incubation process. The two graphs for c=2.5 pM and c=7.5 pM are overlapping at least up to Tᵣ=500 s. In other words, in this regime the number of captured beads on the surface is proportional to the target particle concentration.

The solid line in FIG. 7 represents a simulated curve that takes into consideration the conditions of the experiment according to the formula (with x corresponding to Tᵣ)

$$\frac{S}{c} = {C}_{1} + {C}_{2} ( 1 - exp ( - \frac{x}{τ} ) ) + process ,$$

where C1 accounts for the contribution to the end point signal due to the incubation time of 300 s (for each measurement) and explains the negative values and C2 is the amplitude of the first exponential function, quantity inverse proportional to the analyte concentration. “Process” comprises a second exponential function which corresponds to a process having a much longer relaxation time. Such process can be associated to the contribution of the beads from upper layers. Its influence can be expected at T_{off}>500 ms (when there is enough time to travel a distance equal to the bead diameter). A value for τ of ˜150 s is obtained and connects to the surface reaction mechanism. For a first order reaction scheme we have

$$\frac{1}{τ} = {k}_{on} c + {k}_{off} ,$$

where kₒₙ is the association to the surface constant, c is the concentration of the analyte and k_{off} is the surface dissociation constant. The value of kₒₙ depends also on the concentration of the analyte per bead or the total angular orientation interval within which beads will have the chance to bind to the surface.

FIG. 8 comprises the data for much larger concentrations of target particles (100 pM and 300 pM). Although both curves are linear in a first region, the slopes are different. This is because at these concentrations all beads will have bound more than one target particle. The average number of captured target particles per bead depends on the target particle concentration. As a consequence the estimated characteristic time, from the region of the graph where the slope is positive, is smaller than that for one target molecule per bead. This is due to the fact that the beads will need to reorient less until the binding to the binding surface will take place.

In order to optimize a measurement procedure such that both dynamic range and accuracy are maximized, it is preferred to run an actuation procedure in which the time T_{off} (no magnetic field present) per cycle can be adjusted. At the beginning of the measurement procedure, a given incubation time is allowed such that the kinetics of the process is well under control. The magnetic actuation procedure then starts with high frequencies f (and short relaxation times T_{off}), and the measured detection signal S is compared with calibration curves previously taken for similar conditions. This process is performed following predefined criteria like time dependence of the envelope of the signal. Once it is identified that the signal S approaches a steady state before the allowed time of the measurement is over, a correction (prolongation) of the actuation relaxation time per cycle, T_{off}, is made. The finally reported concentration of the target particles will depend on the history of actuation. It is determined by the evaluation unit 16.

In summary, the invention obtains a control of the dynamic range of an assay by measuring the output signal of a detector and adjusting the magnetic actuation procedure in order to control the orientation of magnetic beads with respect to a binding surface. This is achieved by using proper values for the period during which the magnetic field is switched off per actuation cycle. As a consequence the Brownian rotation of the magnetic beads is delayed influencing the assay kinetics and therefore the final detected signal. The principle is applied in conjunction with the number of the active antibodies per bead. The invention can be applied for example to handheld immunoassay devices including drugs of abuse tests and cardiac tests.

While the invention was described above with reference to particular embodiments, various modifications and extensions are possible, for example:
The detection unit can comprise any suitable sensor to detect the presence of magnetic particles on or near to a sensor surface, based on any property of the particles, e.g. it can detect via magnetic methods (e.g. magnetoresistive, Hall, coils), optical methods (e.g. imaging, fluorescence, chemiluminescence, absorption, scattering, evanescent field techniques, surface plasmon resonance, Raman, etc.), sonic detection (e.g. surface acoustic wave, bulk acoustic wave, cantilever, quartz crystal etc), electrical detection (e.g. conduction, impedance, amperometric, redox cycling), combinations thereof, etc.
A magnetic sensor can be any suitable sensor based on the detection of the magnetic properties of the particle on or near to a sensor surface, e.g. a coil, magneto-resistive sensor, magneto-restrictive sensor, Hall sensor, planar Hall sensor, flux gate sensor, SQUID, magnetic resonance sensor, etc.
Molecular targets often determine the concentration and/or presence of larger moieties, e.g. cells, viruses, or fractions of cells or viruses, tissue extract, etc.
In addition to molecular assays, also larger moieties can be detected with sensor devices according to the invention, e.g. cells, viruses, or fractions of cells or viruses, tissue extract, etc.
The detection can occur with or without scanning of the sensor element with respect to the sensor surface.
The particles serving as labels can be detected directly by the sensing method. As well, the particles can be further processed prior to detection. An example of further processing is that materials are added or that the (bio)chemical or physical properties of the label are modified to facilitate detection.
The device and method can be used with several biochemical assay types, e.g. binding/unbinding assay, sandwich assay, competition assay, displacement assay, enzymatic assay, etc. It is especially suitable for DNA detection because large scale multiplexing is easily possible and different oligos can be spotted via ink jet printing on a substrate.
The device and method are suited for sensor multiplexing (i.e. the parallel use of different sensors and sensor surfaces), label multiplexing (i.e. the parallel use of different types of labels) and chamber multiplexing (i.e. the parallel use of different reaction chambers).
The device and method can be used as rapid, robust, and easy to use point-of-care biosensors for small sample volumes. The reaction chamber can be a disposable item to be used with a compact reader, containing the one or more field generating means and one or more detection means. Also, the device, methods and systems of the present invention can be used in automated high-throughput testing. In this case, the reaction chamber is e.g. a well-plate or cuvette, fitting into an automated instrument.
With nano-particles are meant particles having at least one dimension ranging between 3 nm and 5000 nm, preferably between 10 nm and 3000 nm, more preferred between 50 nm and 1000 nm.

Finally it is pointed out that in the present application the term “comprising” does not exclude other elements or steps, that “a” or “an” does not exclude a plurality, and that a single processor or other unit may fulfill the functions of several means. The invention resides in each and every novel characteristic feature and each and every combination of characteristic features. Moreover, reference signs in the claims shall not be construed as limiting their scope.

1. A sensor device (100) for the detection of magnetic particles (M) in a sample, comprising:
a) a sample camber (1) having a binding surface (12) with binding sites (Z) for magnetic particles (M);
b) a magnetic field generator (20) for attracting magnetic particles (M) to the binding surface (12);
c) a detection unit (13, 14) for providing a detection signal (S) that is related to the amount of magnetic particles (M) bound to the binding surface (12);
d) a controller (15) for controlling the magnetic attraction such that rotational relaxation conditions for the magnetic particles (M) are changed in dependence on the detection signal (S).

2. A method for the detection of magnetic particles (M) in a sample, comprising:
a) magnetically attracting magnetic particles (M) to a binding surface (12) where they can bind to binding sites (Z);
b) detecting with a detection unit (13, 14) magnetic particles (M) that are bound to the binding surface (12);
c) controlling the magnetic attraction such that rotational relaxation conditions for the magnetic particles (M) are changed in dependence on the detection results (S).

3. The sensor device according to claim 1,
characterized in that the magnetic particles (M) can bind at least one target particle (T).

4. The sensor device or the method according to claim 3,
characterized in that only magnetic particles (M) with at least one bound target particle (T) can bind to the binding surface (12).

5. The sensor device according to claim 1,
characterized in that the detection signals (S) of the detection unit (13, 14) are monitored and evaluated by an evaluation unit (16) with respect to the amount of target particles (T) which interact with the magnetic particles (M).

6. The sensor device according to claim 1,
characterized in that the magnetic attraction is controlled to maximize the binding of magnetic particles (M) to the binding surface (12) within a given measurement time.

7. The sensor device according to claim 1,
characterized in that the magnetic attraction is controlled to provide better conditions for rotational relaxation if the detection signal (S) indicates a low binding rate of magnetic particles (M) to the binding surface (12).

8. The sensor device according to claim 2,
characterized in that the control of magnetic attraction is based on stored calibration data.

9. The sensor device according to claim 2,
characterized in that the magnetic attraction oscillates with a controlled frequency.

10. The sensor device according to claim 1,
characterized in that the magnetic attraction is switched between a high and a low value with a controlled duty cycle.

11. The sensor device according to claim 1,
characterized in that the magnetic attraction is a switched off for a controlled duration (T_{off}).

12. The sensor device according to claim 2,
characterized in that unbound magnetic particles (M) are removed from the binding surface (12) before a detection step.

13. The sensor device according to claim 2,
characterized in that the detection unit comprises an optical, magnetic, mechanical, acoustic, thermal or electrical sensor element, particularly a coil, a Hall sensor, a planar Hall sensor, a flux gate sensor, a SQUID, a magnetic resonance sensor, a magneto-restrictive sensor, or magneto-resistive sensor like a GMR, a TMR, or an AMR element.

14. Use of the sensor device according to claim 1 for molecular diagnostics, biological sample analysis, chemical sample analysis, food analysis and/or forensic analysis.
